(19) United States
(12) Patent Application Publication
(10) Pub. No.: US 2002/0056060 A1
(43) Pub. Date: May 9, 2002

(54) Physical layer device testing method, physical layer device with test circuits, and transmitting/receiving circuit with test circuits

(76) Inventors: Noriyuki Saruhashi, Tokyo-to (JP); Hirofumi Kamijo, Tokyo-to (JP)

Correspondence Address: HOGAN & HARTSON L.L.P., 500 S. GRAND AVENUE, SUITE 1900, LOS ANGELES, CA, 90071-2611, US

(21) Appl. No.: 09/871,596

(22) Filed: May 30, 2001

(30) Foreign Application Priority Data
May 31, 2000 (JP) 2000-162546(P)

(51) Int. Cl. G01R 31/28; G06F 11/10

(52) U.S. Cl. 714/712; 714/824

(57) ABSTRACT

A physical layer device 21 includes a link layer interface 2, a physical layer logic circuit 3, and ports 4 to 6. In addition to these components, the physical layer device 21 includes therein a test link layer circuit 22, a test physical layer logic circuit 23, and switches 24 to 26 in order to test the operation of the physical layer logic circuit 3 and the ports 4 to 6. In testing, the ports 4 to 6 are externally connected by a cable 27, and contacts of the switches 24 to 26 are switched. Accordingly, the physical layer logic circuit 3 is connected to the test link layer circuit 22, and the ports 5 and 6 are connected to the test physical layer logic circuit 23. According to the present invention, testing can be performed by a physical layer device alone, thus reducing the test time and the test cost.

### FIELD OF THE INVENTION

The present invention relates to a physical layer device testing method, a physical layer device with test circuits, and a transmitting/receiving circuit with test circuits which can be applied to, for example, a physical layer device (physical layer chip) of an IEEE 1394 interface.

### DESCRIPTION OF THE RELATED ART

Concerning a conventional physical layer device, for example, a physical layer device of an IEEE 1394 interface is known. The physical layer device is formed as illustrated in FIG. 5.

Specifically, a physical layer device 1 includes a link layer interface 2, a physical layer logic circuit 3, and three ports 4 to 6. Accordingly, a single device is formed.

Concerning the physical layer device 1, it is necessary to test, upon shipment or the like, whether or not the operation satisfies each standard defined by the IEEE 1394 standard.

In testing, as shown in FIG. 5, in addition to a link layer device 7 to be connected to the physical layer device 1, it is necessary to provide a physical layer device 8 and a link layer device 9 which are to be connected to the physical layer device 1.

Thus, in testing, the link layer interface 2 of the physical layer device 1 is connected to a physical layer interface 10 of the link layer device 7, and the ports 4 to 6 of the physical layer device 1 are connected to ports 4 to 6, respectively, of the other physical layer device 8 by cables 11. Furthermore, a link layer interface 2 of the physical layer device 8 is connected to a physical layer interface 10 of the link layer device 9.

Concerning the conventional physical layer device 1, when a test is performed to check whether each standard defined by the IEEE 1394 standard is satisfied, not only the link layer device 7 to be connected to the physical layer device 1 but also the other physical layer device 8 and the link layer device 9 are necessary. Thus, it is necessary to perform a test in a special environment, thereby increasing the test time and the test cost.

In FIG. 12, an example of the specific structure of a conventional physical layer device of an IEEE 1394 interface is shown.

The physical layer device includes three cable ports (hereinafter referred to as ports) 101 to 103 for establishing a connection with another IEEE 1394 device. The port 101 includes a driver 104 for transmitting data over a twisted pair cable TPA, a receiver 105 for receiving data over the twisted pair cable TPA, a driver 106 for transmitting data over a twisted pair cable TPB, and a receiver 107 for receiving data over the twisted pair cable TPB. Similarly, the ports 102 and 103 each include the driver 104, the receiver 105, the driver 106, and the receiver 107.

Packets from an upper layer are encoded by a transmission data encoder 108, and the encoded data is input to the drivers 104 and 106 of the ports 101 to 103. Data received by the receivers 105 and 107 of the ports 101 to 103 is decoded by a reception data decoder 109.

In addition to these components, the physical layer device shown in FIG. 12 includes a circuit for adjusting an interconnecting device, an interface circuit with the link layer device, and the like. These circuits are omitted in FIG. 12.

When mass-producing the above-described physical layer device and checking the quality, in general, a predetermined relationship in compliance with the IEEE 1394 standard is established with another IEEE 1394 system (node), and then the ports 101 to 103, which are transmitting/receiving circuits, are tested.

A conventional testing method requires a predetermined sequence according to the IEEE 1394 standard. It is thus necessary to provide another IEEE 1394 system in a tester, and hence a special testing environment is necessary.

When mass-producing the foregoing physical layer device and checking the quality, the test cost is increased. Also, an increase in the test time causes an increase in the production cost (chip cost).

In view of the foregoing circumstances, it is an object of the present invention to provide a physical layer device testing method and a physical layer device with test circuits, which are capable of testing a physical layer device by itself, thereby reducing the test time and the test cost.

It is another object of the present invention to provide a transmitting/receiving circuit with test circuits, which is capable of reducing the test time required for testing a device with transmitting/receiving functions, such as a physical layer device of an IEEE 1394 interface, since it becomes unnecessary to test the device in a special environment, thereby reducing the test cost and the production cost.

### SUMMARY OF THE INVENTION

The present invention provides a method for testing a physical layer device including a link layer interface, a physical layer logic circuit to be connected to the link layer interface, and a plurality of ports to be connected to the physical layer logic circuit. The method is characterized in that a test link layer circuit to be interrelated to the link layer interface and a test physical layer logic circuit to be interrelated to the physical layer logic circuit are provided beforehand in the physical layer device. In testing, the test link layer circuit is connected to the physical layer logic circuit through the link layer interface, and the test physical layer logic circuit is connected to the physical layer logic circuit through the ports. The link layer interface, the physical layer logic circuit, and the ports are tested.

According to the test method of the present invention, the physical layer device can be tested by itself, thus simplifying the testing. As a result, the test time and the test cost can be reduced.

Also, the present invention provides a physical layer device with test circuits, the physical layer device including a link layer interface, a physical layer logic circuit to be connected to the link layer interface, and a plurality of ports to be connected to the physical layer logic circuit. The physical layer device is characterized by including a test link layer circuit for establishing, in testing, a connection with the physical layer logic circuit through the link layer interface and communicating predetermined data with the physical layer logic circuit; and a test physical layer logic circuit for establishing, in testing, a connection with the physical layer logic circuit through the ports and communicating predetermined data with the physical layer logic circuit.

According to the physical layer device with test circuits of the present invention with the foregoing arrangement, in testing, the test link layer circuit is connected to the physical layer logic circuit through the link layer interface and communicates predetermined data with the physical layer logic circuit. The test physical layer logic circuit is connected to the physical layer logic circuit through the ports and communicates predetermined data with the physical layer logic circuit. Thus, predetermined testing of the link layer interface, the physical layer logic circuit, and the ports can be performed.

According to the physical layer device with test circuits of the present invention, the physical layer device can be tested by itself, thus simplifying the testing. Therefore, the test time and the test cost can be reduced.

Concerning an embodiment of the physical layer device with test circuits of the present invention, there is a physical layer device with test circuits, which is characterized in that the link layer interface includes a switch for selectively establishing a connection with an external link layer device or the test link layer circuit, and a predetermined port from among the ports includes a switch for selectively establishing a connection with the physical layer logic circuit or the test physical layer logic circuit.

According to the physical layer device with test circuits of the present invention with the foregoing arrangement, the link layer interface can selectively establish a connection with an external link layer device or the test link layer circuit. Thus, the physical layer device with test circuits of the present invention can be applied not only to a trial product but also to an actual product.

Furthermore, the present invention provides a transmitting/receiving circuit with test circuits, the transmitting/receiving circuit including at least a set of a driver and a receiver. The transmitting/receiving circuit is characterized by including test data storage means for storing test data transmitted by the driver; and comparison means for comparing, when the receiver receives the test data transmitted from the driver, the received test data with the test data stored in the test data storage means.

Concerning an embodiment of the transmitting/receiving circuit with test circuits of the present invention, there is a transmitting/receiving circuit with test circuits, which is characterized in that reception storage means for storing the received test data is provided. The comparison means compares the received test data stored in the reception storage means with the test data stored in the test data storage means.

Concerning an embodiment of the transmitting/receiving circuit with test circuits of the present invention, there is a transmitting/receiving circuit with test circuits, which is characterized in that the test data storage means and the reception storage means are formed of registers. The registers operate in synchronization based on the same clock.

According to the transmitting/receiving circuit with test circuits of the present invention with the foregoing arrangement, in testing, at the same time test data is input to the driver, the test data is stored in the test data storage means. The test data transmitted from the driver is received by the receiver. The comparison means compares the received test data with the test data stored in the test data storage means. The comparison result obtained by the comparison means is monitored using a monitor.

According to the transmitting/receiving circuit with test circuits of the present invention, it becomes unnecessary to test the transmitting/receiving circuit in a special testing environment, thus reducing the test time. As a result, the test cost and the production cost can be reduced.

The present invention also provides a transmitting/receiving circuit with test circuits, the transmitting/receiving circuit including at least a set of a first driver and a first receiver and another set of a second driver and a second receiver. The transmitting/receiving circuit is characterized by including test data storage means for storing test data transmitted by the first driver; and comparison means for comparing, when the first receiver and the second receiver each receive the test data transmitted by the first driver, each of the received test data with the test data stored in the test data storage means.

Concerning an embodiment of the transmitting/receiving circuit with test circuits of the present invention, there is a transmitting/receiving circuit with test circuits, which is characterized in that first reception storage means for storing the received test data received by the first receiver and second reception storage means for storing the received test data received by the second receiver are provided. The comparison means includes first comparison means for comparing the received test data stored in the first reception storage means with the test data stored in the test data storage means; and second comparison means for comparing the received test data stored in the second reception storage means with the test data stored in the test data storage means.

Concerning an embodiment of the transmitting/receiving circuit with test circuits of the present invention, there is a transmitting/receiving circuit with test circuits, which is characterized in that the test data storage means, the first reception storage means, and the second reception storage means are formed of registers. The registers operate in synchronization based on the same clock.

According to the transmitting/receiving circuit with test circuits of the present invention with the foregoing arrangement, prior to testing, the first driver and the second receiver are interconnected by an external wire connection. In testing, at the same time test data is transferred to the first driver, the test data is stored in the test data storage means. The test data transmitted from the first driver is received by the first receiver and the second receiver, respectively. The comparison means compares each of the received test data with the test data stored in the test data storage means. The comparison results obtained by the comparison means are monitored using a monitor.

According to the transmitting/receiving circuit with test circuits of the present invention, it becomes unnecessary to test the transmitting/receiving circuit in a special testing environment, thus reducing the test time. As a result, the test cost and the production cost can be reduced.

Furthermore, the present invention provides a transmitting/receiving circuit with test circuits, the transmitting/receiving circuit including a set of a first driver and a first receiver and another set of a second driver and a second receiver. The transmitting/receiving circuit with test circuits is characterized by including test data storage means for storing test data; selection means for selecting inputting of the test data to the first driver or the second driver; and comparison means for comparing, when the first receiver and the second receiver each receive the test data transmitted by the first driver, each of the received test data with the test data stored in the test data storage means and for comparing, when the second receiver receives the test data transmitted by the second driver, the received test data with the test data stored in the test data storage means.

Concerning an embodiment of the transmitting/receiving circuit with test circuits of the present invention, there is a transmitting/receiving circuit with test circuits, which is characterized in that first reception storage means for storing the received test data received by the first receiver and second reception storage means for storing the received test data received by the second receiver are provided. The comparison means includes first comparison means for comparing the received test data stored in the first reception storage means with the test data stored in the test data storage means; and second comparison means for comparing the received test data stored in the second reception storage means with the test data stored in the test data storage means.

Concerning an embodiment of the transmitting/receiving circuit with test circuits of the present invention, there is a transmitting/receiving circuit with test circuits, which is characterized in that the test data storage means, the first reception storage means, and the second reception storage means are formed of registers. The registers operate in synchronization based on the same clock.

According to the transmitting/receiving circuit with test circuits of the present invention with the foregoing arrangement, prior to testing, the first driver and the second receiver are interconnected by an external wire connection. In testing, at the same time test data is input to the first driver by the selection means, the test data is stored in the test data storage means. The test data transmitted from the first driver is received by the first receiver and the second receiver, respectively. The comparison means compares each of the received test data with the test data stored in the test data storage means. The comparison results obtained by the comparison means are monitored using a monitor.

Next, the test data stored in the test data storage means is input to the second driver by the selection means. The test data transmitted from the second driver is received by the second receiver. The comparison means compares the received test data with the test data stored in the test data storage means. The comparison result obtained by the comparison means is monitored using a monitor.

According to the transmitting/receiving circuit with test circuits of the present invention, it becomes unnecessary to test the transmitting/receiving circuit in a special testing environment, thus reducing the test time. As a result, the test cost and the production cost can be reduced.

Concerning an embodiment of the transmitting/receiving circuit with test circuits of the present invention, there is a transmitting/receiving circuit with test circuits, which is characterized in that the transmitting/receiving circuit is a physical layer device of an IEEE 1394 interface.

### BRIEF DESCRIPTION OF THE DRAWINGS

FIG. 1 is a block diagram of a physical layer device with test circuits according to an embodiment of the present invention, which is applied to a physical layer device of an IEEE 1394 interface;

FIG. 2 is a block diagram of an example of the specific structure of a physical layer logic circuit;

FIG. 3 is a block diagram of an example of the structure of a test link layer circuit;

FIG. 4 is a block diagram of the specific structure of a test physical layer logic circuit;

FIG. 5 is an illustration of the related art;

FIG. 6 is a block diagram of a transmitting/receiving circuit with test circuits according to a first embodiment of the present invention, which is applied to the physical layer device of the IEEE 1394 interface;

FIG. 7 is a block diagram of details of the test circuits of the first embodiment;

FIG. 8 is a block diagram of a transmitting/receiving circuit with test circuits according to a second embodiment of the present invention, which is applied to the physical layer device of the IEEE 1394 interface;

FIG. 9 is a block diagram of details of the test circuits of the second embodiment;

FIG. 10 is a block diagram of a transmitting/receiving circuit with test circuits according to a third embodiment of the present invention, which is applied to the physical layer device of the IEEE 1394 interface;

FIG. 11 is a block diagram of a transmitting/receiving circuit with test circuits according to a fourth embodiment of the present invention, which is applied to the physical layer device of the IEEE 1394 interface, in which a portion of the physical layer device is illustrated; and

FIG. 12 is a block diagram of an example of the specific structure of a conventional physical layer device of an IEEE 1394 interface.

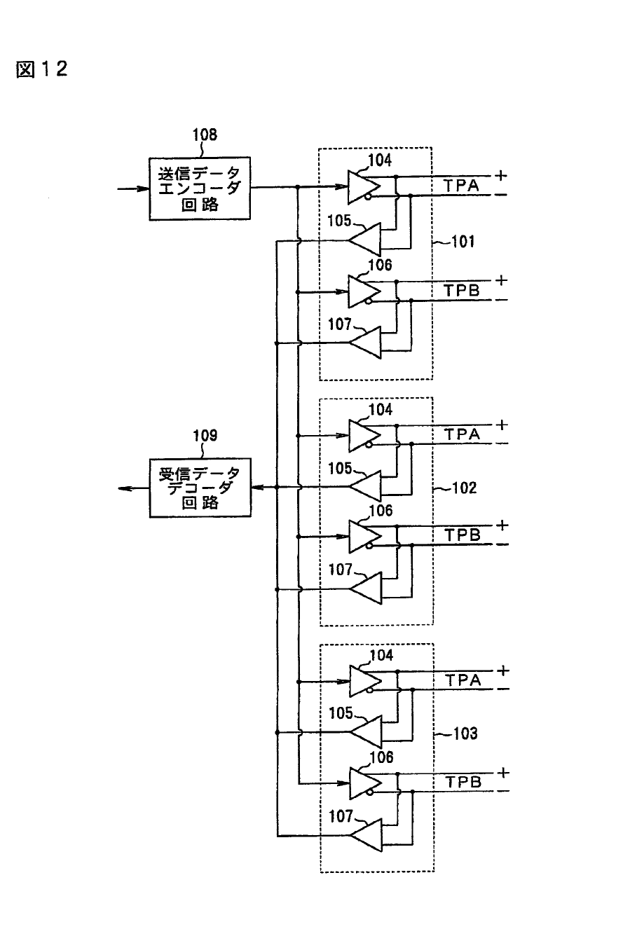

### DESCRIPTION OF THE PREFERRED EMBODIMENTS

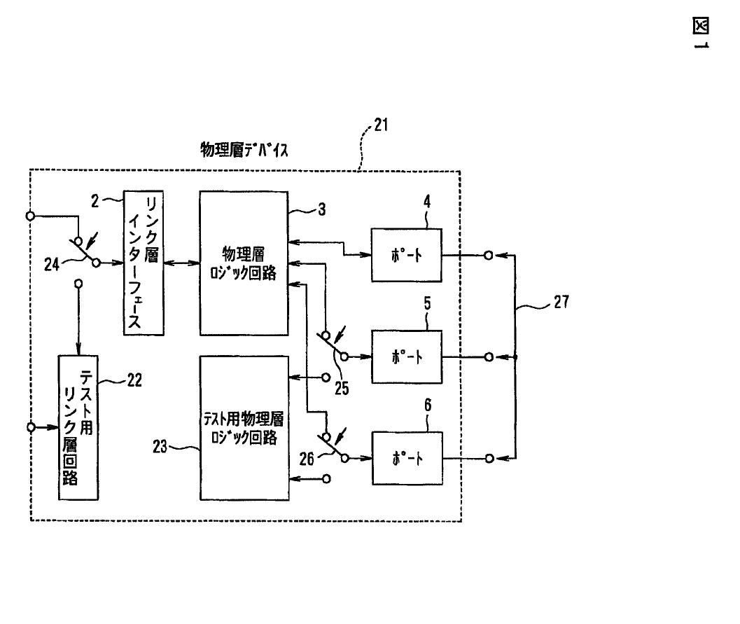

Embodiments of a physical layer device testing method and a physical layer device with test circuits are described with reference to FIGS. 1 to 4.

FIG. 1 is a block diagram of a physical layer device with test circuits of the embodiment, which is applied to a physical layer device of an IEEE 1394 interface.

As shown in FIG. 1, a physical layer device 21 includes a link layer interface 2, a physical layer logic circuit 3, and ports 4 to 6. In addition to these components, the physical layer device 21 includes in advance a test link layer circuit 22, a test physical layer logic circuit 23, and selector switches 24 to 26 for testing the operation of the link layer interface 2, the physical layer logic circuit 3, and the ports 4 to 6.

The link layer interface 2 communicates predetermined data with an external link layer device or the test link layer device circuit 22.

The physical layer logic circuit 3 communicates predetermined data with an external physical layer logic circuit or the test physical layer logic circuit 23 through the ports 4 to 6. At the same time, the physical layer logic circuit 3 encodes transmission data, decodes reception data, adjusts data transmission and reception, or the like.

The ports 4 to 6 each include a driver (not shown) for transmitting data and a receiver (not shown) for receiving data. The port 4 is always connected to the physical layer logic circuit 3. In normal operation, the ports 5 and 6 are connected to the physical layer logic circuit 3 side by switches 25 and 26. In testing, the ports 5 and 6 are connected to the test physical layer logic circuit 23 by switching the switches 25 and 26.

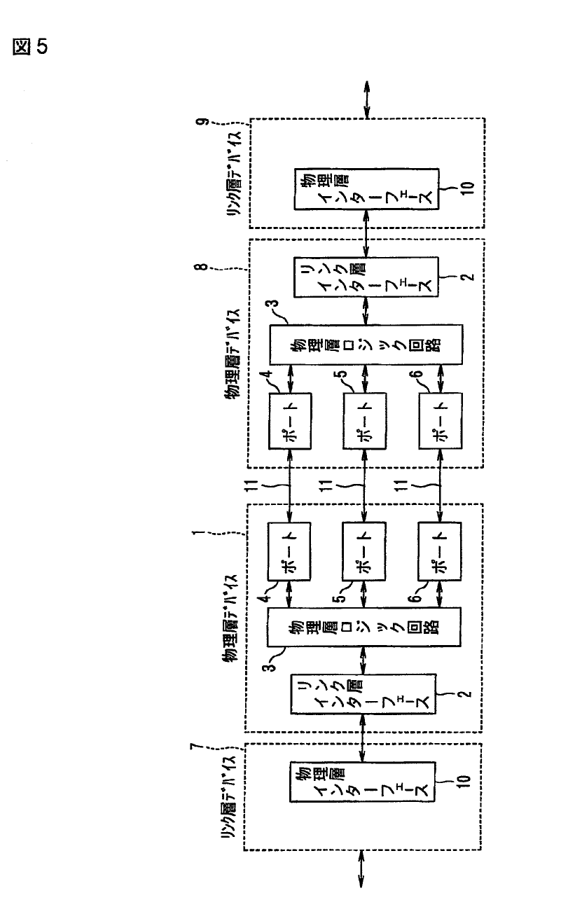

The test link layer circuit 22 corresponds to the link layer device 7 shown in FIG. 5. In testing, the test link layer circuit 22 is connected to the physical layer logic circuit 3 through the link layer interface 2 and performs testing as described hereinafter.

The test physical layer logic circuit 23 corresponds to the physical layer device 8 shown in FIG. 5. In testing, the test physical layer logic circuit 23 is connected to the physical layer logic circuit 3 through the ports 4 to 6, and performs testing as described hereinafter.

The switch 24 includes a switchable contact. In normal operation, the contact is at a position shown in FIG. 1. In testing, the contact is switched from the position shown in FIG. 1 to the opposite side in response to a control signal from the test link layer circuit 22.

The switches 25 and 26 have switchable contacts. In normal operation, the contacts are at positions shown in FIG. 1. In testing, the contacts are switched from the positions shown in FIG. 1 to the opposite side in response to a control signal from the test physical layer logic circuit 23.

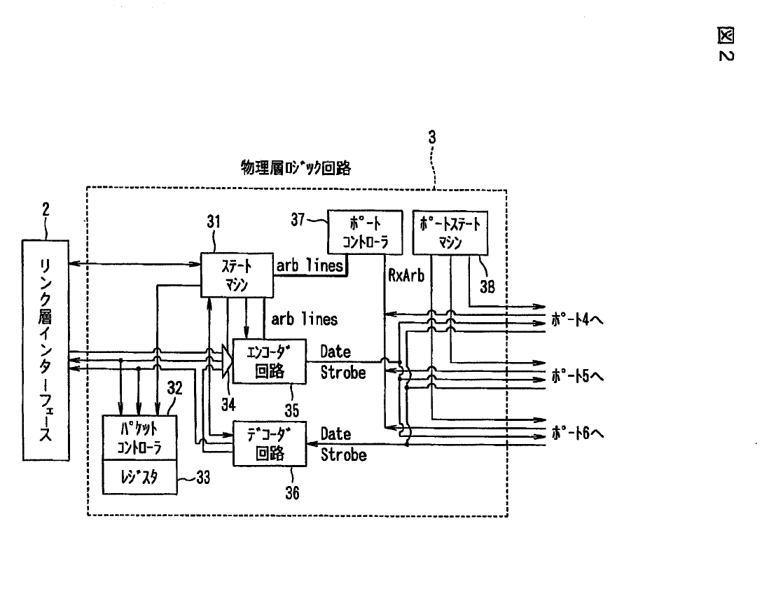

An example of the specific structure of the physical layer logic circuit 3 will now be described with reference to FIG. 2.

As shown in FIG. 2, the physical layer logic circuit 3 includes a state machine 31, a packet controller 32, a register 33, a selector 34, an encoder circuit 35, a decoder circuit 36, a port controller 37, and a port state machine 38.

The state machine 31 controls each part. The packet controller 32 generates predetermined packets in cooperation with the register 33. The selector 34 selectively supplies a signal from each part to the encoder circuit 35.

The encoder circuit 35 encodes transmission data and supplies the data to the drivers in the ports 4 to 6. The decoder circuit 36 decodes reception data received by the receivers in the ports 4 to 6. The port controller 37 controls transmission and reception performed by the ports 4 to 6. The port state machine 38 adjusts the ports 4 to 6.

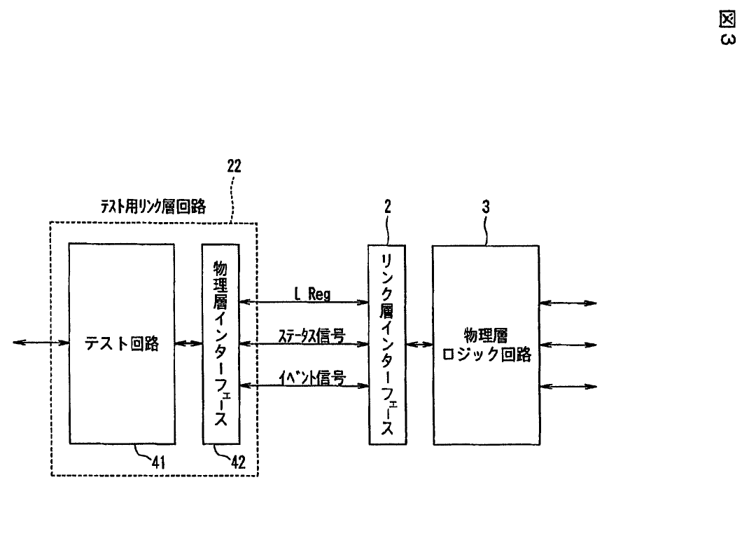

An example of the structure of the test link layer circuit 22 will now be described with reference to FIG. 3.

As shown in FIG. 3, the test link layer circuit 22 includes a test circuit 41 and a physical layer interface 42. In testing, the test circuit 41 generates predetermined packets and utilizes the packets to communicate data with the physical layer logic circuit 3 through a predetermined procedure. Thus, the test circuit 41 has a different structure depending on the content of testing.

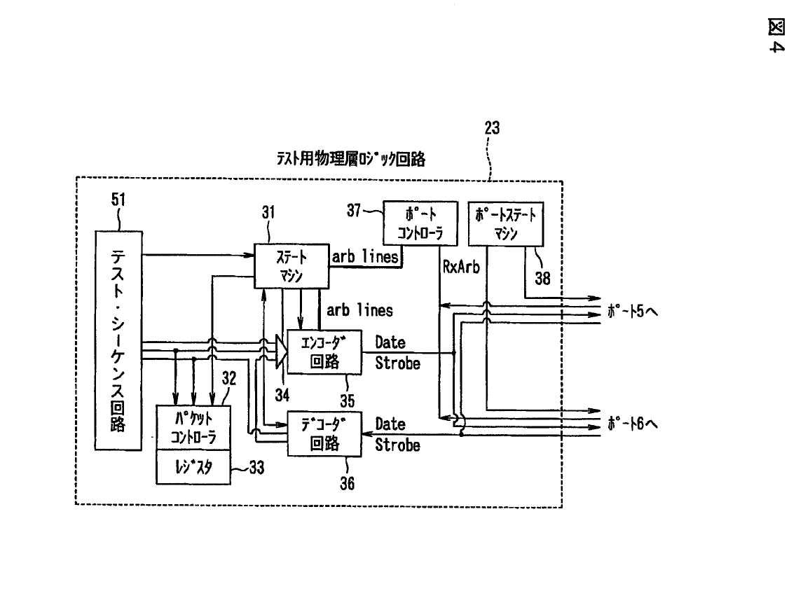

An example of the specific structure of the test physical layer logic circuit 23 will now be described with reference to FIG. 4.

As shown in FIG. 4, the test physical layer logic circuit 23 basically has the same structure as that of the physical layer logic circuit 3 shown in FIG. 2. The test physical layer logic circuit 23 differs from the physical layer logic circuit 3 in that the test physical layer logic circuit 23 includes a test sequence circuit 51.

The test sequence circuit 51 corresponds to the link layer device 9 shown in FIG. 5. In testing, the test sequence circuit 51 controls each part through a predetermined procedure in order that the test physical layer logic circuit 23 generates transmission data to be supplied to the drivers in the ports 5 and 6 and process reception data from the ports 5 and 6.

Since the remaining structure is the same as that shown in FIG. 2, the same reference numerals are given to components corresponding to those in FIG. 2, and descriptions of the common portions are omitted.

An example of a process of testing the physical layer device 21 of the embodiment will now be described.

Prior to testing, as shown in FIG. 1, external connection terminals of the ports 4 to 6 are externally connected.

When testing starts in this state, the contact of the switch 24 is switched from the position shown in FIG. 1 to the opposite position in response to a control signal from the test link layer circuit 22. The contacts of the switches 25 and 26 are switched from the positions shown in FIG. 1 to the opposite positions in response to a control signal from the test physical layer logic circuit 23.

Subsequently, the test circuit 41 of the test link layer circuit 22 starts operating. Specifically, the test circuit 41 generates predetermined packets and communicates predetermined signals with the physical layer logic circuit 3 based on the packets (see FIG. 3). For example, concerning the signals, there is a link request signal LReq defined in the IEEE 1394 standard, a status signal, an event signal, and the like. Each signal is output externally by appropriate means and is monitored, and hence the operation of the link layer interface 2 and the physical layer logic circuit 3 is checked.

At the same time, the test physical layer logic circuit 23 also starts operating. Specifically, the test sequence circuit 51 of the test physical layer logic circuit 23 generates transmission data to be supplied by each part of the test physical layer logic circuit 23 to the drivers in the ports 5 and 6. Also, the test sequence circuit 51 controls each part through a predetermined procedure so that each part processes reception data from the ports 5 and 6. Data is thus communicated between the physical layer logic circuit 3 and the test physical layer logic circuit 23 through the ports 4 to 6.

For example, transmission data from the physical layer logic circuit 3 and reception data from the test physical layer logic circuit 23 are output externally through appropriate means and are monitored. Also, transmission data from the test physical layer logic circuit 23 and reception data from the physical layer logic circuit 3 are output externally through appropriate means and are monitored. As a result, the operation of the physical layer logic circuit 3 and the ports 4 to 6 are checked.

As described above, according to this embodiment, it is possible to perform predetermined testing by the physical layer device 21 alone. As a result, the testing is simplified, and the test time and the test cost are reduced.

According to this embodiment, the link layer interface 2 is selectively connected to an external link layer device or to the test link layer circuit 22 by the switch 24. Thus, the physical layer device 21 can be applied not only to a trial product but also to an actual product.

According to the foregoing embodiment, the physical layer device 21 includes the switch 24, and hence the physical layer device 21 is applicable not only to a trial product but also to an actual product. Alternatively, the present invention can be applied only to a trial product. In this case, the switch 24 can be omitted.

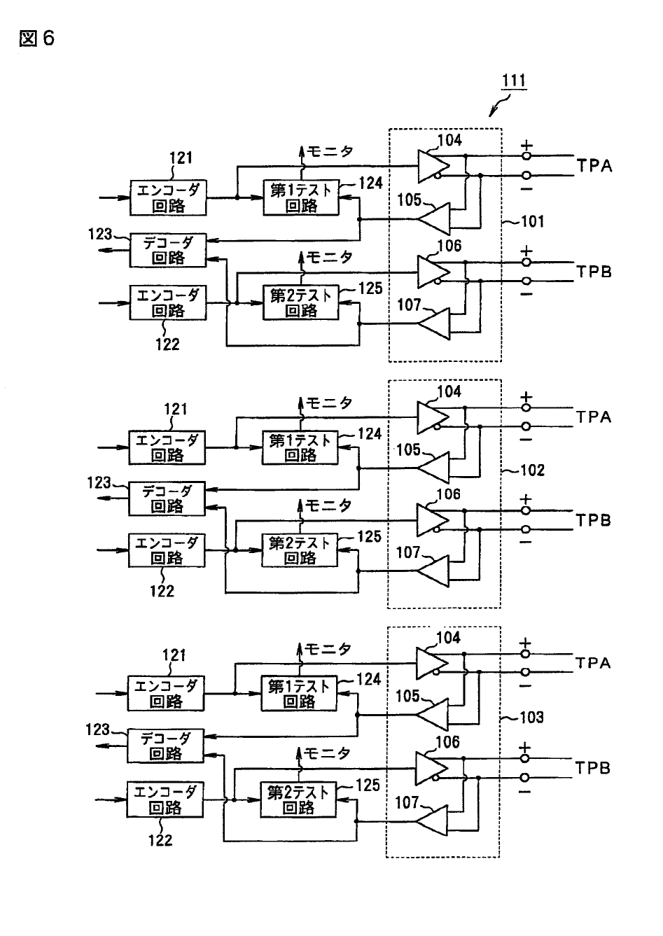

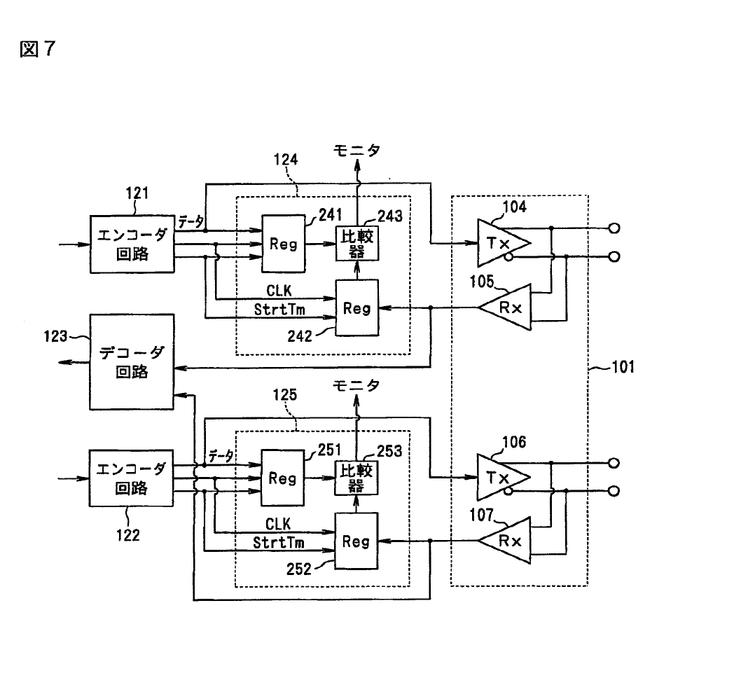

A transmitting/receiving circuit with test circuits according to a first embodiment of the present invention will now be described with reference to FIGS. 6 and 7.

FIG. 6 is a block diagram of a transmitting/receiving circuit with test circuits of the first embodiment, which is applied to the physical layer device of the IEEE 1394 interface.

As shown in FIG. 6, a physical layer device 11 includes three ports 101 to 103 for establishing a connection with another IEEE 1394 device and transmitting and receiving data. The ports 101 to 103 each include encoder circuits 121 and 122 and a decoder circuit 123. In addition to these components, the ports 101 to 103 each include a first test circuit 124 and a second test circuit 125 for testing the operation of the ports. In normal operation, the test circuits 124 and 125 are not used. The test circuits 124 and 125 are only used in testing.

The port 101 includes a first driver 104 for transmitting data and a first receiver 105 for receiving data. The driver 104 and the receiver 105 are grouped into a set. Also, the port 101 includes a second driver 106 for transmitting data and a second receiver 107 for receiving data. The driver 106 and the receiver 107 are grouped into a set.

The input side of the driver 104 is connected to the encoder circuit 121 and the first test circuit 124. The output side of the driver 104 is connected to the input side of the receiver 105 and to a twisted pair cable (TPA). The input side of the receiver 105 is connected to the output side of the driver 104, and the output side of the receiver 105 is connected to the decoder circuit 123 and the first test circuit 124.

The input side of the driver 106 is connected to the encoder circuit 122 and the second test circuit 125, and the output side of the driver 106 is connected to the input side of the receiver 107 and a twisted pair cable (TPB). The input side of the receiver 107 is connected to the output side of the driver 106, and the output side of the receiver 107 is connected to the decoder circuit 123 and the second test circuit 125.

As shown in FIG. 6, the ports 102 and 103 are similarly formed as the port 101. Thus, the same reference numerals are given to the corresponding components, and descriptions of the common portions are omitted.

In addition to the above-described components, the physical layer device 111 shown in FIG. 6 includes a circuit for adjusting a connecting device, an interface circuit with a link layer device, and the like. In FIG. 6, however, these circuits are omitted.

The detailed structure of the first test circuit 124 and the second test circuit 125 will now be described with reference to FIG. 7.

The first test circuit 124 includes a register 241 as a test data storage means for storing test data output from the encoder circuit 121 in testing; a register 242 as a reception storage means for storing test data received by the receiver 105 in testing; and a comparator 243 for comparing the received test data stored in the register 242 with the test data stored in the register 241 in testing. An output signal of the comparator 243 is output externally and is monitored.

The register 241 and the register 242 operate in synchronization based on the same clock CLK. A signal StrtTm which is asserted when effective data is transmitted is supplied from the encoder circuit 121 to the registers 241 and 242. After the signal StrtTm is asserted, and after delay time of the driver 104 and the receiver 105 passes, the register 242 stores data.

The second test circuit 125 includes a register 251 for storing test data output from the encoder circuit 122 in testing; a register 252 for storing test data received by the receiver 107 in testing; and a comparator 253 for comparing the received test data stored in the register 252 with the test data stored in the register 251 in testing. An output signal of the comparator 253 is output externally and is monitored.

The register 251 and the register 252 operate in synchronization based on the same clock CLK. A signal StrtTm which is asserted when effective data is transmitted is supplied from the encoder circuit 122 to the registers 251 and 252. After the signal StrtTm is asserted, and after delay time of the driver 106 and the receiver 107 passes, the register 252 stores data.

Referring to FIG. 7, the operation is described in which the port 101 is tested by the first test circuit 124 and the second test circuit 125 according to the first embodiment.

When external packet data is input to the encoder circuit 121, the packet data is encoded. The encoder circuit 121 outputs test data. The test data is transferred to the driver 104. Also, the test data is stored in the register 241. The test data input to the driver 104 is converted by the driver 104 into a differential signal and is output. The differential signal is received by the receiver 105 and is converted into the original test data. The test data is stored in the register 242.

The comparator 243 compares the received test data stored in the register 242 with the test data stored in the register 241 and outputs an output signal concerning the comparison result. By monitoring the output signal from the comparator circuit 243, the operation of the driver 104 and the receiver 105 can be checked.

In contrast, when external packet data is input to the encoder circuit 122, the packet data is encoded. The encoder circuit 122 outputs test data. The test data is transferred to the driver 106. Also, the test data is stored in the register 251. The test data input to the driver 106 is converted by the driver 106 into a differential signal and is output. The differential signal is received by the receiver 107 and is converted into the original test data. The test data is stored in the register 252.

The comparator 253 compares the received test data stored in the register 252 with the test data stored in the register 251 and outputs an output signal concerning the comparison result. By monitoring the output signal from the comparator circuit 253, the operation of the driver 106 and the receiver 107 can be checked.

The above operation is for testing the port 101. Since testing the other ports 102 and 103 is similar to this operation, repeated descriptions thereof are omitted.

As described above, according to the first embodiment, with the first test circuit 124, the operation of the driver 104 and the receiver 105 can be checked in a short period of time. With the second test circuit 125, the operation of the driver 106 and the receiver 107 can be checked in a short period of time.

According to the test circuits, it becomes unnecessary to test the ports 101 to 103 of the physical layer device 111 in a special testing environment, thus reducing the test time. Accordingly, the test cost and the production cost of the physical layer device 111 can be reduced.

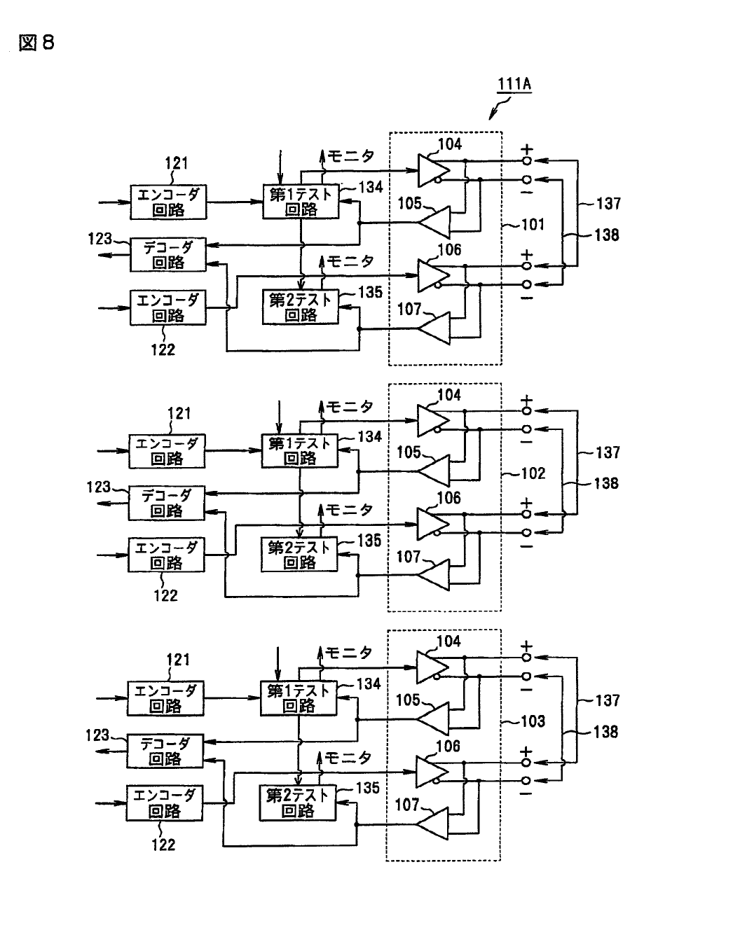

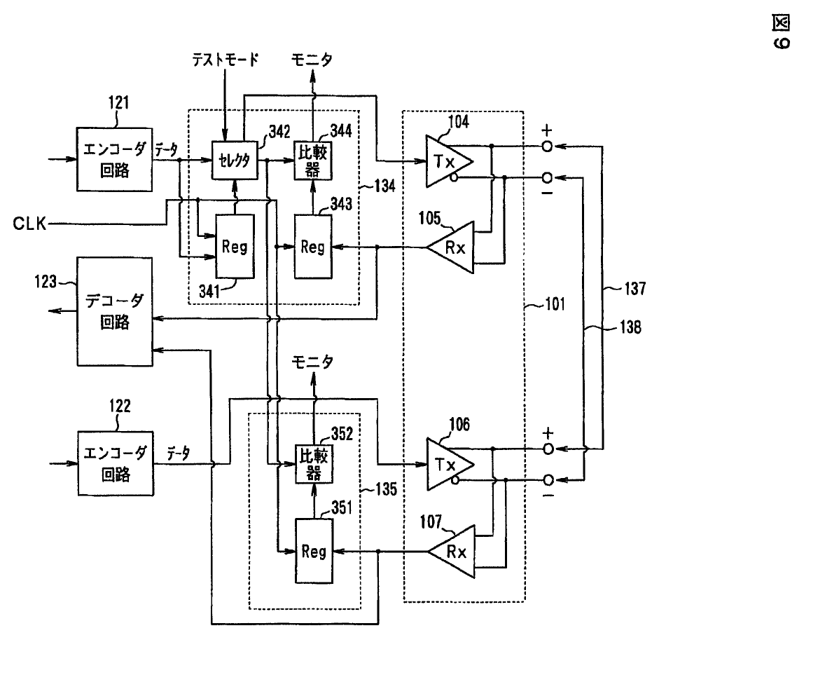

A transmitting/receiving circuit with test circuits according to a second embodiment of the present invention will now be described with reference to FIGS. 8 and 9.

FIG. 8 is a block diagram of a transmitting/receiving circuit with test circuits of the second embodiment, which is applied to a physical layer device 111A of the IEEE 1394 interface.

Concerning the physical layer device 111A, the first test circuits 124 and the second test circuits 125 of the ports 101 to 103 of the physical layer device 111 shown in FIG. 6 are replaced by first test circuits 134 and second test circuits 135, as shown in FIG. 8.

The physical layer device 111A has the same structure as that of the physical layer device 111 shown in FIG. 6 except for the test circuits 134 and 135. Thus, the same reference numerals are given to components corresponding to those in FIG. 6, and descriptions of the common portions are omitted.

The detailed structure of each first circuit 134 and each second circuit 135 will now be described with reference to FIG. 9.

As shown in FIG. 9, the first test circuit 134 includes a register 341 as a test data storage means, a selector 342, a register 343 as a reception storage means, and a comparator 344. The registers 341 and 343, and a register 351 (described hereinafter) of the second test circuit 135 operate in synchronization based on, for example, a low-speed test clock CLK at approximately 50 MHz.

The register 341 stores beforehand test data output from the encoder 121. In normal operation, the selector 342 transfers output data of the encoder 121 to the driver 104. In testing in which a test mode is externally set, the selector 342 transfers test data stored in the register 341 to the driver 104 and to the comparator 344.

In the test mode, the register 343 stores received test data from the receiver 105. In the test mode, the comparator 344 compares the received test data stored in the register 343 with the test data stored in the register 341. An output signal of the comparator 344 is output externally and is monitored.

As shown in FIG. 9, the second test circuit 135 includes the register 351 as a reception storage means and a comparator 352.

In the test mode, the register 351 stores received test data received by the receiver 107. In the test mode, the comparator 352 compares the received test data stored in the register 351 with the test data stored in the register 341. An output signal from the comparator 352 is output externally and is monitored.

Referring to FIG. 9, the operation is described in which the port 101 is tested by the first test circuit 134 and the second test circuit 135 of the second embodiment.

In this case, prior to testing, as shown in FIG. 9, positive terminals of the output side of the driver 104 and the driver 106 are electrically interconnected by an external wire 137. Also, negative terminals of the output side of the drivers 104 and 106 are electrically interconnected by an external wire 138. In the encoder 121, test data obtained by encoding externally input packet data is stored beforehand.

In this state, when a test mode is externally set, the selector 342 causes the test data stored in the register 341 to be transmitted to the driver 104 and to the comparator 344.

The test data transmitted to the driver 104 is converted by the driver 104 into a differential signal and is output. The differential signal is received by the receiver 105 and is converted into the original test data. The test data is stored in the register 343. The comparator 344 compares the received test data stored in the register 343 with the test data stored in the register 341 and outputs an output signal concerning the comparison result. By monitoring the output signal from the comparator circuit 344, the operation of the driver 104 and the receiver 105 can be checked.

In contrast, the differential signal output from the driver 104 is received by the receiver 107 and is converted into the original test data. The test data is stored in the register 351. The comparator 352 compares the received test data stored in the register 351 with the test data stored in the register 341 and outputs an output signal concerning the comparison result. By monitoring the output signal from the comparator circuit 352, the operation of the receiver 107 can be checked.

The above operation is for testing the port 101. Since testing the other ports 102 and 103 is similar to this operation, repeated descriptions thereof are omitted. When testing the ports 102 and 103, as shown in FIG. 8, an external connection is established by the external wires 137 and 138.

The registers 341 and 343 and the register 351 operate in synchronization based on, for example, a low-speed test clock CLK at approximately 50 MHz. Thus, for example, when delay of the driver 104 and the receiver 105 is 10 μs, the comparators 344 and 352 can compare received test data with test data because the period of the clock CLK is 20 nS. Accordingly, comparison between reception data and test data can be performed without paying attention to reception timing as in the first embodiment.

As described above, according to the test circuits of the second embodiment, with the first test circuits 134, the operation of the drivers 104 and the receivers 105 can be checked in a short period of time. With the second test circuits 135, the operation of the receivers 107 can be checked in a short period of time.

According to the test circuits of the second embodiment, it becomes unnecessary to test the ports 101 to 103 of the physical layer device 111A in a special testing environment, thus reducing the test time. Accordingly, the test cost and the production cost of the physical layer device 111A can be reduced.

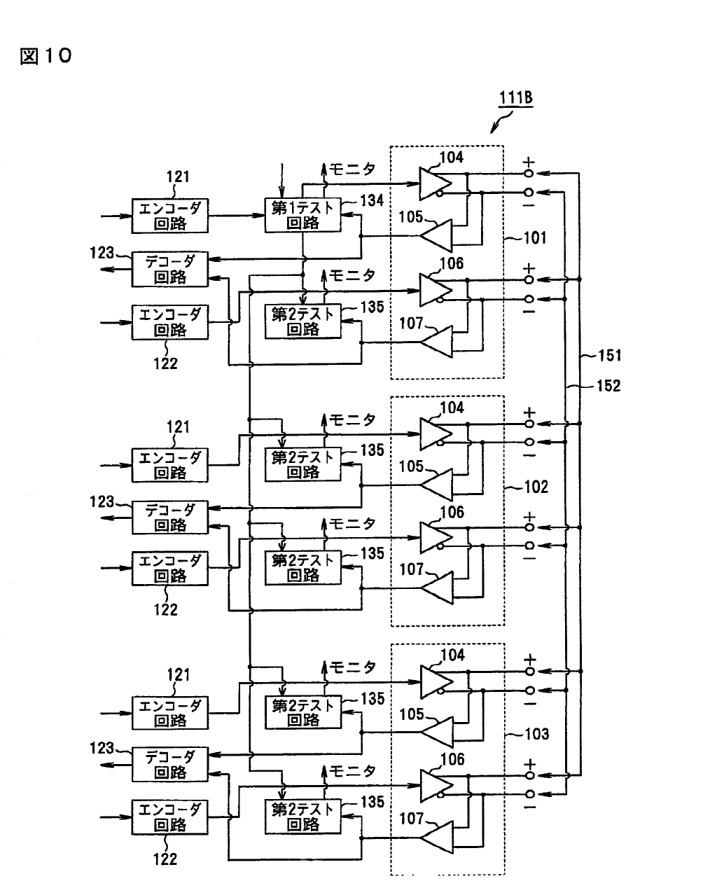

Referring to FIG. 10, a transmitting/receiving circuit with test circuits according to a third embodiment of the present invention will now be described.

FIG. 10 is a block diagram of a transmitting/receiving circuit with test circuits of the third embodiment, which is applied to a physical layer device 111B of the IEEE 1394 interface.

Concerning the physical layer device 111B, the first test circuits 134 of the ports 102 and 103 of the physical layer device 111A shown in FIG. 8 are replaced by the second test circuits 135 as shown in FIG. 10.

Since the physical layer device 111B has the same structure as that of the physical layer device 111A shown in FIG. 8 except for the replacing second test circuits 135, the same reference numerals are given to components corresponding to those in FIG. 8, and descriptions of the common portions are omitted.

According to the physical layer device 111B with such a structure, in testing, an external connection is established as shown in FIG. 10. Specifically, positive terminals of the output side of the drivers 104 and 106 of the ports 101 to 103 are electrically interconnected by an external wire 151, and negative terminals of the output side of the drivers 104 and 106 are electrically interconnected by an external wire 152.

Testing the port 101 is similar to testing the port 101 of the physical layer device 111A. In contrast, concerning the ports 102 and 103, the contents of testing are as follows.

Specifically, the receivers 105 and 107 of the ports 102 and 103 receive output data from the driver 104 of the port 101, and the received test data are stored in the registers 351 of the second test circuits 135 (see FIG. 9).

The comparators 352 in the second test circuits 135 compare the received test data with test data stored in the register 341 of the first test circuit 134 and outputs output signals concerning the comparison results. By monitoring the output signals from the comparator circuits 352, the operation of the receivers 105 and 107 can be checked.

According to the test circuits of the third embodiment, it becomes unnecessary to test the ports 101 to 103 of the physical layer device 111B in a special testing environment, thus reducing the test time. As a result, the test cost and the production cost of the physical layer device 111B can be reduced.

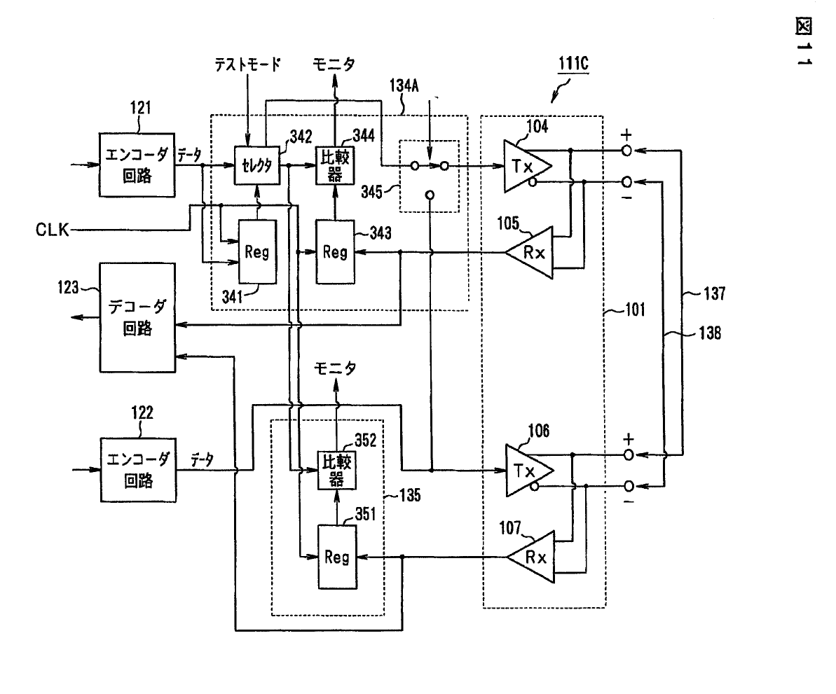

A transmitting/receiving circuit with test circuits according to a fourth embodiment of the present invention will now be described with reference to FIG. 11.

FIG. 11 is a block diagram of a transmitting/receiving circuit with test circuits of the fourth embodiment, which is applied to a physical layer device 111C of the IEEE 1394 interface, in which a portion of the physical layer device 111C is illustrated.

As shown in FIG. 11, concerning the physical layer device 111C, the first test circuit 134 of the physical layer device 111A shown in FIG. 9 is replaced by a first test circuit 134A.

Since the physical layer device 111C has the same components such as the second test circuit 135 and the like as those of the physical layer device 111A shown in FIG. 9 except for the first test circuit 134A, the same reference numerals are given to components corresponding to those in FIG. 9, and descriptions of the common portions are omitted.

As shown in FIG. 11, the first test circuit 134A includes the register 341, the selector 342, the register 343, the comparator 344, and a selector switch 345.

In normal operation, a switchable contact of the selector switch 345 is fixed to a position shown in FIG. 11. In a test period, at the beginning, the switchable contact is at the position shown in the drawing, and test data stored in the register 341 is transferred to the driver 104. Subsequently, the switchable contact is changed to a position opposite to the shown position, and the test data is transferred to the driver 106.

Since the structure of the register 341, the selector 342, the register 343, and the comparator 344 is similar to that of the first test circuit 134 shown in FIG. 10, repeated descriptions thereof are omitted.

Referring to FIG. 11, the operation is described in which the port 1 is tested by the first test circuit 134A and the second test circuit 135 of the fourth embodiment.

In this case, prior to testing, as shown in FIG. 11, positive terminals of the output side of the drivers 104 and the driver 106 are electrically interconnected by the external wire 137. Also, negative terminals of the output side of the driver 104 and the driver 106 are electrically interconnected by the external wire 138. Test data obtained by encoding external packet data which is input to the encoder circuit 121 is stored beforehand in the register 341.

In this state, when a test mode is externally set, the test data stored in the register 341 is transferred to the driver 104 through the selector 342 and the selector switch 345. Also, the test data is transferred to the comparator 344 through the selector 342.

The test data transferred to the driver 104 is converted by the driver 104 into a differential signal and is output. The differential signal is received by the receiver 105 and is converted into the original test data. The test data is stored in the register 343. The comparator 344 compares the received test data stored in the register 343 with the test data stored in the register 341 and outputs an output signal concerning the comparison result. By monitoring the output signal from the comparator circuit 344, the operation of the driver 104 and the receiver 105 can be checked.

In contrast, the differential signal output from the driver 104 is received by the receiver 107 and is converted into the original test data. The test data is stored in the register 351. The comparator 352 compares the received test data stored in the register 351 with the test data stored in the register 341 and outputs an output signal concerning the comparison result. By monitoring the output signal from the comparator circuit 352, the operation of the receiver 107 can be checked.

Next, in response to a switch changing-over signal, the switchable contact of the selector switch 345 is changed to a position opposite to that shown in FIG. 11. Thus, the test data stored in the register 341 is transferred to the driver 106 through the selector 342 and the selector switch 345. The test data transferred to the driver 106 is converted by the driver 106 into a differential signal and is output.

The differential signal is received by the receiver 107 and is converted into the original test data. The test data is stored in the register 351. The comparator 352 compares the received test data stored in the register 351 with the test data stored in the register 341 and outputs an output signal concerning the comparison result. By monitoring the output signal from the comparator circuit 352, the operation of the driver 106 and the receiver 107 can be checked.

As described above, according to the test circuits of the fourth embodiment, with the first test circuit 134A, the operation of the driver 104 and the receiver 105 can be checked in a short period of time. With the second test circuit 135, the operation of the driver 106 and the receiver 107 can be checked in a short period of time.

According to the test circuits of the fourth embodiment, it becomes unnecessary to test the ports 101 to 103 of the physical layer device 111C in a special testing environment, thus reducing the test time. Accordingly, the test cost and the production cost of the physical layer device 111C can be reduced.

Industrial Applicability

As described above, according to a physical layer device testing method and a physical layer device with test circuits of the present invention, testing can be performed by a physical layer device alone. The testing is simplified, and the test time and the test cost are reduced.

According to a transmitting/receiving circuit with test circuits of the present invention, the test circuits for testing transmission/reception functions are provided. For example, when the present invention is applied to a device with transmission/reception functions such as a physical layer device of the IEEE 1394 interface, it becomes unnecessary to test the device in a special testing environment, thus reducing the test time. Accordingly, the test cost and the production cost can be reduced.

What is claimed is:

1. A method for testing a physical layer device including a link layer interface, a physical layer logic circuit to be connected to said link layer interface, and a plurality of ports to be connected to said physical layer logic circuit, said method characterized in that:
a test link layer circuit to be interrelated to said link layer interface and a test physical layer logic circuit to be interrelated to said physical layer logic circuit are provided beforehand in said physical layer device;
in testing, said test link layer circuit is connected to said physical layer logic circuit through said link layer interface, and said test physical layer logic circuit is connected to said physical layer logic circuit through said plurality of ports; and
said link layer interface, said physical layer logic circuit, and said plurality of ports are tested.

2. A physical layer device with test circuits, said physical layer device including a link layer interface, a physical layer logic circuit to be connected to said link layer interface, and a plurality of ports to be connected to said physical layer logic circuit, said physical layer device characterized by comprising:
a test link layer circuit for establishing, in testing, a connection with said physical layer logic circuit through said link layer interface and communicating predetermined data with said physical layer logic circuit; and
a test physical layer logic circuit for establishing, in testing, a connection with said physical layer logic circuit through said plurality of ports and communicating predetermined data with said physical layer logic circuit.

3. A physical layer device with test circuits according to claim 2, characterized in that:
said link layer interface includes a switch for selectively establishing a connection with an external link layer device or said test link layer circuit; and
a predetermined port from among said plurality of ports includes a switch for selectively establishing a connection with said physical layer logic circuit or said test physical layer logic circuit.

4. A transmitting/receiving circuit with test circuits, said transmitting/receiving circuit including at least a set of a driver and a receiver, characterized by comprising:
test data storage means for storing test data transmitted by said driver; and
comparison means for comparing, when said receiver receives the test data transmitted from said driver, the received test data with the test data stored in said test data storage means.

5. A transmitting/receiving circuit with test circuits according to claim 4, characterized in that:
reception storage means for storing the received test data is provided; and
said comparison means compares the received test data stored in said reception storage means with the test data stored in said test data storage means.

6. A transmitting/receiving circuit with test circuits according to claim 5, characterized in that:
said test data storage means and said reception storage means are formed of registers; and
the registers operate in synchronization based on the same clock.

7. A transmitting/receiving circuit with test circuits, said transmitting/receiving circuit including at least a set of a first driver and a first receiver and another set of a second driver and a second receiver, characterized by comprising:
test data storage means for storing test data transmitted by said first driver; and
comparison means for comparing, when said first receiver and said second receiver each receive the test data transmitted by said first driver, each of the received test data with the test data stored in said test data storage means.

8. A transmitting/receiving circuit with test circuits according to claim 7, characterized in that:
first reception storage means for storing the received test data received by said first receiver and second reception storage means for storing the received test data received by the second receiver are provided; and
said comparison means includes first comparison means for comparing the received test data stored in said first reception storage means with the test data stored in said test data storage means; and second comparison means for comparing the received test data stored in said second reception storage means with the test data stored in said test data storage means.

9. A transmitting/receiving circuit with test circuits according to claim 8, characterized in that said test data storage means, said first reception storage means, and said second reception storage means are formed of registers; and said registers operate in synchronization based on the same clock.

10. A transmitting/receiving circuit with test circuits, said transmitting/receiving circuit including a set of a first driver and a first receiver and another set of a second driver and a second receiver, characterized by comprising:
test data storage means for storing test data;
selection means for selecting inputting of the test data to said first driver or said second driver; and
comparison means for comparing, when said first receiver and said second receiver each receive the test data transmitted by said first driver, each of the received test data with the test data stored in said test data storage means and for comparing, when said second receiver receives the test data transmitted by said second driver, the received test data with the test data stored in said test data storage means.

11. A transmitting/receiving circuit with test circuits according to claim 10, characterized in that:
first reception storage means for storing the received test data received by said first receiver and second reception storage means for storing the received test data received by said second receiver are provided; and
said comparison means includes first comparison means for comparing the received test data stored in said first reception storage means with the test data stored in said test data storage means; and second comparison means for comparing the received test data stored in said second reception storage means with the test data stored in said test data storage means.

12. A transmitting/receiving circuit with test circuits according to claim 11, characterized in that said test data storage means, said first reception storage means, and said second reception storage means are formed of registers; and the registers operate in synchronization based on the same clock.

13. A transmitting/receiving circuit with test circuits according to any one of claims 4 to 12, characterized in that said transmitting/receiving circuit is a physical layer device of an IEEE 1394 interface.
